(19) United States
(12) Patent Application Publication
(10) Pub. No.: US 2008/0088008 A1
(43) Pub. Date: Apr. 17, 2008

(54) SEMICONDUCTOR PACKAGE HAVING PAD ARRANGEMENT

(75) Inventors: Hyun-A KIM, Suwon-si (KR); Dong-Han KIM, Osan-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/858,244

(22) Filed: Sep. 20, 2007

(30) Foreign Application Priority Data
Oct. 12, 2006 (KR) 10-2006-0099112

(51) Int. Cl. H01L 23/52

(52) U.S. Cl. 257/691; 257/E23.079

(57) ABSTRACT

A semiconductor package includes a semiconductor chip, multiple first outer connection pads positioned along a first edge of the semiconductor chip in a first direction, and multiple first outer connection leads electrically connected to the first outer connection pads. Multiple first power pads extend from the first edge of the semiconductor chip in a second direction substantially perpendicular to the first direction. A first power lead is electrically connected to the first power pads.

### CROSS-REFERENCE TO RELATED APPLICATION

A claim of priority is made to Korean Patent Application No. 10-2006-0099112, filed on Oct. 12, 2006, the subject matter of which is hereby incorporated by reference.

### BACKGROUND OF THE INVENTION

1. Field of the Invention

Example embodiments of the present invention relate to a semiconductor package. More particularly, embodiments of the present invention relate to a semiconductor package having an integrated arrangement of connection and power/ground pads.

2. Description of the Related Art

Recently, cellular phones and other personal communication devices increasingly include various additional functions in response to demands from a diverse range of customers. Therefore, semiconductor packages having capacities corresponding to the various functions may be incorporated into these devices.

For example, conventional cellular phones may include many input/output signals. To effectively transmit the input/output signals, a chip-on-film (COF) package, including a semiconductor chip mounted on an organic film, may be employed in such cellular phones.

FIG. 1 is a plan view illustrating a conventional a semiconductor package 1, such as a conventional COF package. Referring to FIG. 1, the conventional COF package includes a semiconductor chip 10, first outer connection pads 20, second outer connection pads 22, power pads 24, ground pads 26, first outer connection leads 30, second outer connection leads 32, a power lead 34 and a ground lead 36.

The first outer connection pads 20 are arranged on an edge of the semiconductor chip 10 along a first direction that corresponds to a lengthwise direction of the semiconductor chip 10. The second outer connection pads 22 are arranged on another edge of the semiconductor chip 10 along a second direction substantially perpendicular to the first direction. The first outer connection leads 30 are electrically connected to the first outer connection pads 20, respectively. Further, the second outer connection leads 32 are electrically connected to the second outer connection pads 22, respectively.

The power pads 24 and the ground pads 26 are arranged along the edge of the semiconductor chip 10 in the first direction between the first outer connection pads 20. The single power lead 34 is branched into five leads, which are electrically connected to the power pads 24, respectively. Further, the single ground lead 36 is branched into five leads, which are electrically connected to the ground pads 26, respectively.

In the conventional COF package, the power pads 24 and the ground pads 26 are arranged along the first direction, which is the direction in which the first outer connection pads 20 are aligned. Thus, a pitch between the first outer connection pads 20 may be overly narrow. Since the pitch between the first outer connection pads 20 is very narrow, a pitch between the patterns on a film of the COF package, electrically connected to the first outer connection pads 20, may also be very narrow. To form the patterns on the film having such a narrow pitch, precise processes may be required, which may result in a high cost of the COF package.

Further, to test the COF package, contact probes may be required to contact the first and the second connection pads 20 and 22, respectively. However, since the first and the second outer connection pads 20 and 22 have the narrow pitches, forming separate contacts between the first and the second outer connection pads 20 and 22, as well as forming the narrow probes, may be difficult. As a result, to accurately contact the probes to the first and the second outer connection pads 20 and 22, it may be necessary to provide the probes with a minute pitch. A cost of manufacturing the probe having the minute pitch may also be high.

Furthermore, a current transmission speed may be proportional to a width of the leads. However, since the leads may have a very narrow pitch, the width of the leads may likewise be very narrow. Particularly, the power leads may have a width substantially the same as that of the ground lead. This may cause a low power transmission speed.

The above-mentioned problems may result in increased expense and/or deterioration of the COF package.

### SUMMARY OF THE INVENTION

An aspect of the present invention provides a semiconductor package, including a semiconductor chip, multiple first outer connection pads positioned along a first edge of the semiconductor chip in a first direction and multiple first outer connection leads electrically connected to the first outer connection pads. The semiconductor packing also includes multiple first power pads extending from the first edge of the semiconductor chip in a second direction substantially perpendicular to the first direction, and a first power lead electrically connected to the first power pads.

The first power lead may have a width greater than a width of each of the first outer connection leads. Also, the first power lead may be parallel to the first outer connection leads.

The semiconductor package may further include multiple second outer connection pads positioned along a second edge of the semiconductor chip in the second direction and multiple second outer connection leads electrically connected to the second outer connection pads. The semiconductor package may also include multiple second power pads extending from the second edge of the semiconductor chip in the first direction and a second power lead electrically connected to the second power pads. The second power lead may have a width greater than a width of each of the second outer connection leads. Also, the second power lead may be parallel to the second outer connection leads.

The semiconductor package may further include multiple first ground pads extending from the first edge of the semiconductor chip in the second direction, and a first ground lead electrically connected to the first ground pads. The ground lead may have a width greater than a width of each of the first outer connection leads. Also, the ground lead may be parallel to the first outer connection leads.

The semiconductor package may further include multiple second outer connection pads positioned along a second edge of the semiconductor chip in the second direction and multiple second outer connection leads electrically connected to the second outer connection pads. The semiconductor package may also include multiple second ground pads extending from the second edge of the semiconductor chip in the first direction and a second ground power electrically connected to the second ground pads. The second ground lead may have a width greater than a width of each of the second outer connection leads. Also, the second ground lead may be parallel to the second outer connection leads.

Another aspect of the present invention provides a semiconductor package, including a semiconductor chip; multiple first outer connection pads arranged in a first direction along a first edge of the semiconductor chip; multiple first outer connection leads electrically connected to the first outer connection pads; multiple second outer connection pads arranged in a second direction along a second edge of the semiconductor chip, the second direction being substantially perpendicular to the first direction; and multiple second outer connection leads electrically connected to the second outer connection pads. Multiple first power pads extend from the first edge of the semiconductor chip in the second direction, and a first power lead is electrically connected to the first power pads. Multiple first ground pads also extend from the first edge of the semiconductor chip in the second direction, and a first ground lead is electrically connected to the first ground pads. The semiconductor package may be a chip-on-film (COF) package.

The semiconductor package may further include multiple second power pads extending from the second edge of the semiconductor chip in the first direction, and a second power lead is electrically connected to the second power pads. Multiple second ground pads also extend from the second edge of the semiconductor chip in the first direction, and a second ground lead is electrically connected to the second ground pads. One of the first power pads and one of the first ground pads may be aligned in the first direction with the first outer connection leads along the first edge of the semiconductor chip.

### BRIEF DESCRIPTION OF THE DRAWINGS

The embodiments of the present invention will be described with reference to the attached drawings, in which:

FIG. 1 is a plan view illustrating a conventional semiconductor package;

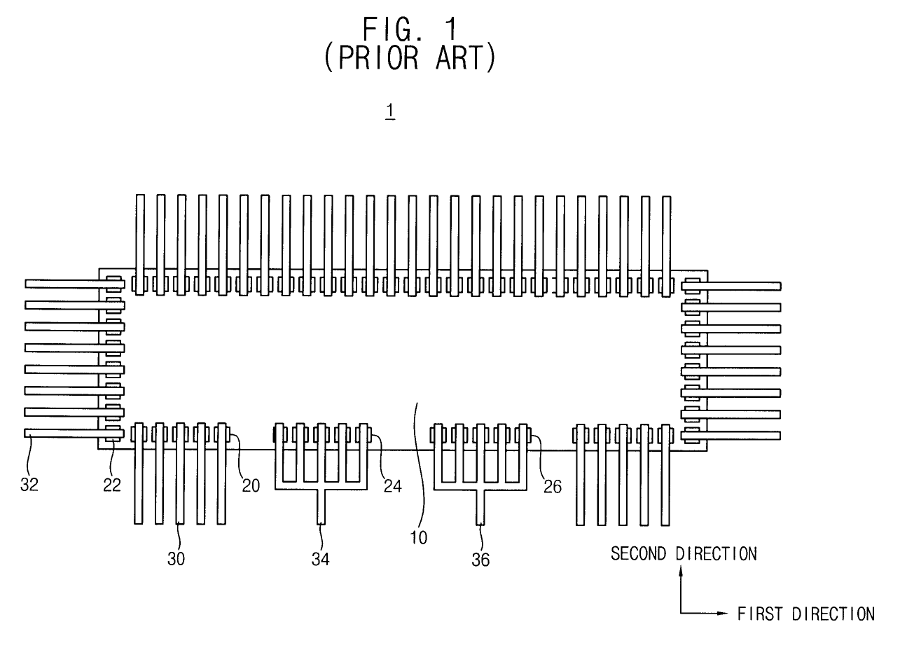

FIG. 2 is a plan view illustrating a semiconductor package in accordance with a first exemplary embodiment of the present invention; and

FIG. 3 is a plan view illustrating a semiconductor package in accordance with a second exemplary embodiment of the present invention.

### DESCRIPTION OF THE EMBODIMENTS

The present invention is described more fully with reference to the accompanying drawings, in which embodiments of the invention are shown. This invention may, however, be embodied in various different forms and should not be construed as being limited to the illustrated embodiments. Rather, these embodiments are provided as examples, to convey the concept of the invention to one skilled in the art. Accordingly, known processes, elements, and techniques are not described with respect to some of the embodiments of the present invention. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Throughout the drawings and written description, like reference numerals will be used to refer to like or similar elements. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the spirit and scope of the disclosed embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation of above and below. Likewise, the device may be otherwise oriented (e.g., rotated 90 degrees or at other orientations) and the spatially relative descriptors should be interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having meanings that consistent with the context of the relevant art and will not be interpreted in an idealized or overly formal sense unless expressly so provided.

### First Example Embodiment

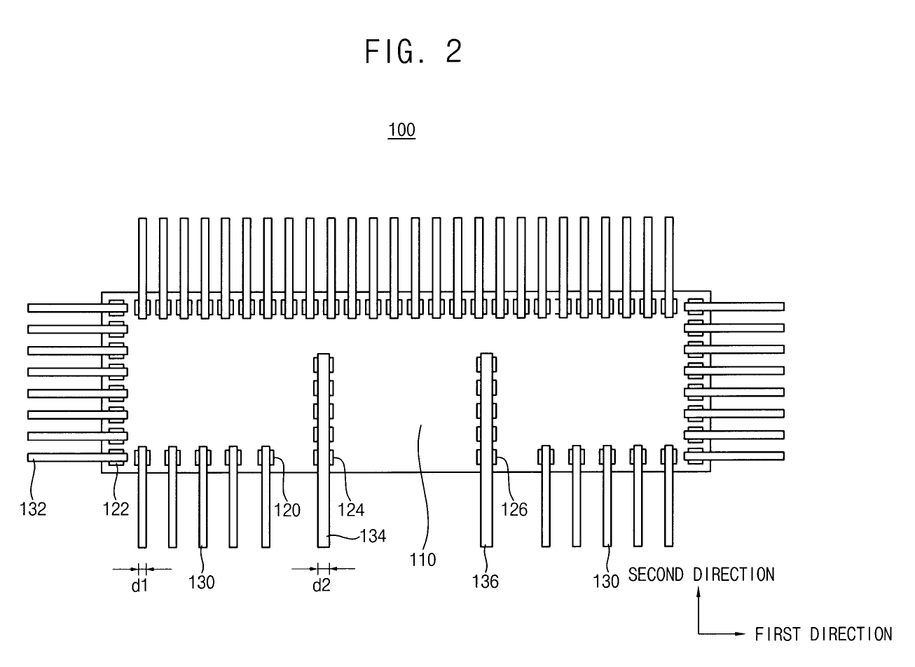

FIG. 2 is a plan view illustrating a semiconductor package in accordance with a first exemplary embodiment of the present invention.

Referring to FIG. 2, a semiconductor package 100 of the depicted embodiment may be a chip-on-film (COF) package. For example, the semiconductor package 100 may correspond to a display driver integrated circuit (DDI) package for driving a liquid crystal display (LCD) device of a cellular phone. The semiconductor package 100 includes a semiconductor chip 110, first outer connection pads 120, second outer connection pads 122, power pads 124, ground pads 126, first outer connection leads 130, second outer connection leads 132, a single power lead 134, and a single ground lead 136.

The semiconductor chip 110 may have a substantially rectangular shape. Thus, the semiconductor chip 110 has two long sides opposite to each other, and two short sides opposite to each other and substantially perpendicular to the two long sides. The ends of each of the two short sides are respectively connected to ends of the two long sides.

The first outer connection pads 120 are arranged along first edges of the semiconductor chip 110 in a first direction, which is substantially parallel with the long sides of the semiconductor chip 110. The second outer connection pads 122 are arranged along second edges of the semiconductor chip in a second direction, which is substantially perpendicular to the first direction. In other words, the second direction is substantially parallel with the short sides of the semiconductor chip 110. As a result, the first and the second outer connection pads 120 and 122 are respectively arranged along the first and the second edges of the semiconductor chip 110 to generally form a rectangular frame shape.

The first outer connection leads 130 are electrically connected to the first outer connection pads 120, respectively. In the depicted embodiment, the first outer connection leads 130 may be arranged along the first direction and extend parallel to one another in the second direction. Likewise, the second outer connection leads 132 are electrically connected to the second outer connection pads 122, respectively. In the depicted embodiment, the second outer connection leads 132 may be arranged along the second direction and extend parallel to one another in the first direction.

The power pads 124 are arranged on the semiconductor chip 110 between the first outer connection pads 120. In the depicted embodiment, the power pads 124 are arranged in the second direction, such that an end power pad 124 is positioned closest to the first edge of the semiconductor chip 110 and the remaining power pads 124 extend in the second direction away from the first edge. That is, the direction in which the power pads 124 are arranged may be substantially perpendicular to the direction of the first outer connection pads 120. In an embodiment, the end power pad 124 may also be substantially aligned with the outer connection pads 120 positioned along the first edge.

The single power lead 134 is electrically connected to the power pads 124. Because the power pads 124 are aligned in the second direction, the power lead 134 extends across the power pads 124 also in the second direction.

The ground pads 126 are arranged on the semiconductor chip 110 between the first outer connection pads 120. In the depicted embodiment, the ground pads 126 are arranged in the second direction, such that an end ground pad 126 is positioned along the first edge of the semiconductor chip 110 and the remaining ground pads 126 extend in the second direction away from the first edge. That is, the direction in which the ground pads 124 are arranged may be substantially perpendicular to the direction of the first outer connection pads 120. In an embodiment, the first ground pad 126 may also be substantially aligned with the outer connection pads 120 positioned along the first edge.

The single ground lead 136 is electrically connected to the ground pads 126. Because the ground pads 126 are aligned along the second direction, the ground lead 136 extends across the ground pads 126 also in the second direction.

The power pads 124 and the ground pads 126 are positioned along the second direction to provide sufficient space for the first outer connection pads 120 to be widely spaced along the first direction on the semiconductor chip 110. Therefore, a pitch between the first outer connection pads 120 may be sufficiently widened. As a result, for example, probes used for testing the semiconductor package 100 may accurately contact each of the first outer connection pads 120, so that the semiconductor package 100 may be easily and efficiently tested. Further, since circuit patterns of the semiconductor package 100 and the probes may have wider pitches, the manufacturing costs of the semiconductor package 100 and the probes may be reduced.

Further, the additional space on the semiconductor chip 110 enables the first outer connection leads 130 and the power lead 134 to be sufficiently wide. In particular, the power lead 134, which transmits power to the semiconductor chip 110, may have a width d2, which is greater than a width d1 of each first outer connection lead 130. Therefore, the power may be rapidly and efficiently transmitted through the power lead 134, enhancing the capabilities of the semiconductor package 100.

According to the first exemplary embodiment, the direction in which the power pads 124 and the ground pads 126 are aligned may be substantially perpendicular to the direction in which the first outer connection pads 120 are aligned. Therefore, the space in which the first outer connection pads 120 are positioned in the first direction may be guaranteed on the semiconductor chip 110. As a result, the first outer connection pads 120 may have a wide pitch.

### Second Example Embodiment

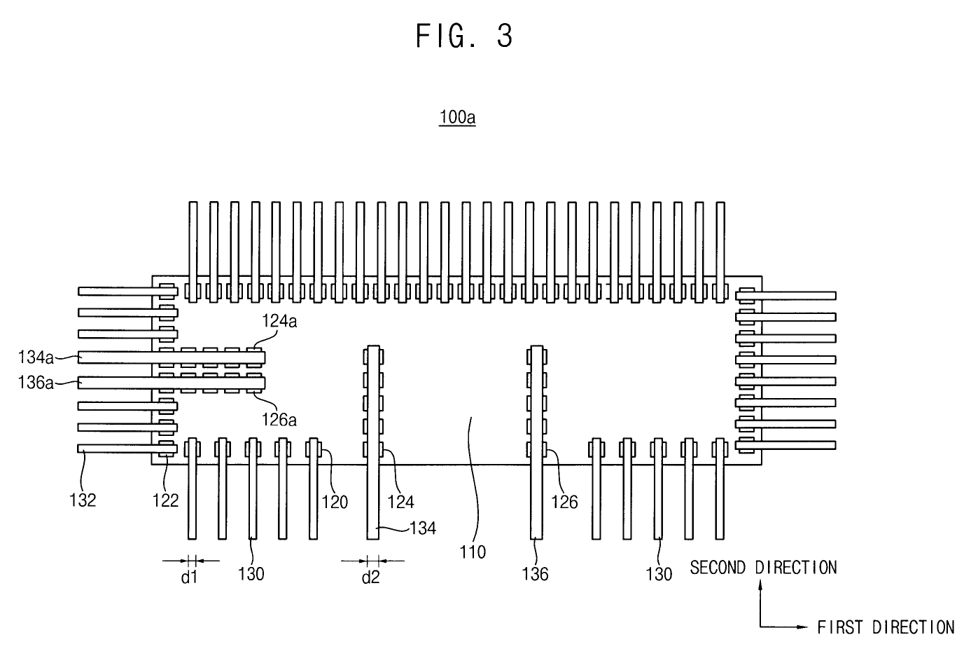

FIG. 3 is a plan view illustrating a semiconductor package in accordance with a second exemplary embodiment of the present invention.

The semiconductor package 100a of the depicted embodiment substantially includes the elements of the semiconductor package 100 of the First Example Embodiment, except that additional second power pads 124a, second ground pads 126a, a second power lead 134a and a second ground lead 136a are included. Therefore, the same reference numerals refer to the same elements depicted in FIG. 2, described above, and further illustrations and descriptions of these elements are not repeated herein for the sake of brevity.

Referring to FIG. 3, the second power pads 124a and the second ground pads 126a are positioned between the second outer connection pads 122. In the depicted embodiment, the second power pads 124a and the second ground pads 126a are arranged in the first direction. In other words, the second power pads 124a and the second ground pads 126a may extend from the second edge of the semiconductor device 110 in a direction substantially perpendicular to the direction in which the second outer connection pads 122 are aligned. Also, in an embodiment, a second power pad 124a and a second ground pad 126a closest to the second edge of the semiconductor device 110 may also be substantially aligned with the second outer connection pads 122.

Further, the second power lead 134a extends in the first direction, and is electrically connected to the second power pads 124a. The second ground lead 136a also extends in the first direction, and is electrically connected to the second ground pads 126a.

According to the depicted embodiment, the second power pads 124a and the second ground pads 126a are arranged in a direction substantially perpendicular to the direction in which the second outer connection pads 122 are arranged, extending from the second edge of the semiconductor device 110. Therefore, the semiconductor chip 110 may provide sufficient space for the second outer connection pads 122 to be arranged in the second direction. As a result, the second outer connection pads 122 may have a wider pitch.

In the exemplary embodiments, the semiconductor package may be a COF package, for example. Alternatively, the embodiments may be included in other types of semiconductor packages having connection pads, power pads and ground pads, without departing from the spirit and scope of the present invention.

According to embodiments of the present invention, power pads and ground pads are generally arranged substantially perpendicular to the direction in which outer connection pads are arranged, so that the pitch between the outer connection pads may be widened. Also, probes may make better contact with the outer connection pads due to the increased width. As a result, the semiconductor chip may be readily tested using the probes.

Further, costs of manufacturing the semiconductor package and the probes may be reduced. Furthermore, the current transmission speed through the wider leads may be greater, improving the capabilities and capacities of semiconductor package.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A semiconductor package comprising:
a semiconductor chip;
a plurality of first outer connection pads positioned along a first edge of the semiconductor chip in a first direction;
a plurality of first outer connection leads electrically connected to the first outer connection pads;
a plurality of first power pads extending from the first edge of the semiconductor chip in a second direction substantially perpendicular to the first direction; and
a first power lead electrically connected to the first power pads.

2. The semiconductor package of claim 1, wherein the first power lead comprises a width greater than a width of each of the first outer connection leads.

3. The semiconductor package of claim 1, wherein the first power lead is parallel to the first outer connection leads.

4. The semiconductor package of claim 1, further comprising:
a plurality of second outer connection pads positioned along a second edge of the semiconductor chip in the second direction;
a plurality of second outer connection leads electrically connected to the second outer connection pads;
a plurality of second power pads extending from the second edge of the semiconductor chip in the first direction; and
a second power lead electrically connected to the second power pads.

5. The semiconductor package of claim 4, wherein the second power lead comprises a width greater than a width of each of the second outer connection leads.

6. The semiconductor package of claim 4, wherein the second power lead is parallel to the second outer connection leads.

7. The semiconductor package of claim 1, further comprising:
a plurality of first ground pads extending from the first edge of the semiconductor chip in the second direction; and
a first ground lead electrically connected to the first ground pads.

8. The semiconductor package of claim 7, wherein the ground lead comprises a width greater than a width of each of the first outer connection leads.

9. The semiconductor package of claim 7, wherein the ground lead is parallel to the first outer connection leads.

10. The semiconductor package of claim 7, further comprising:
a plurality of second outer connection pads positioned along a second edge of the semiconductor chip in the second direction;
a plurality of second outer connection leads electrically connected to the second outer connection pads;
a plurality of second ground pads extending from the second edge of the semiconductor chip in the first direction; and
a second ground power electrically connected to the second ground pads.

11. The semiconductor package of claim 10, wherein the second ground lead comprises a width greater than a width of each of the second outer connection leads.

12. The semiconductor package of claim 10, wherein the second ground lead is parallel to the second outer connection leads.

13. A semiconductor package comprising:
a semiconductor chip;
a plurality of first outer connection pads arranged in a first direction along a first edge of the semiconductor chip;
a plurality of first outer connection leads electrically connected to the first outer connection pads;
a plurality of second outer connection pads arranged in a second direction along a second edge of the semiconductor chip, the second direction being substantially perpendicular to the first direction;
a plurality of second outer connection leads electrically connected to the second outer connection pads;
a plurality of first power pads extending from the first edge of the semiconductor chip in the second direction;
a first power lead electrically connected to the first power pads;
a plurality of first ground pads extending from the first edge of the semiconductor chip in the second direction; and
a first ground lead electrically connected to the first ground pads.

14. The semiconductor package of claim 13, wherein the first power lead and the first ground lead each have a width greater than a width of each of the first outer connection leads and the second outer connection leads.

15. The semiconductor package of claim 13, wherein the first power lead, the first ground lead and the first outer connection leads are in parallel.

16. The semiconductor package of claim 13, further comprising:
a plurality of second power pads extending from the second edge of the semiconductor chip in the first direction; and
a second power lead electrically connected to the second power pads;
a plurality of second ground pads extending from the second edge of the semiconductor chip in the first direction; and
a second ground lead electrically connected to the second ground pads.

17. The semiconductor package of claim 16, wherein the second power lead and the second ground lead each comprise a width greater than a width of each of the first outer connection leads and the second outer connection leads.

18. The semiconductor package of claim 16, wherein the second power lead, the second ground lead and the second outer connection leads are in parallel.

19. The semiconductor package of claim 13, wherein one of the first power pads and one of the first ground pads is aligned in the first direction with the first outer connection leads along the first edge of the semiconductor chip.

20. The semiconductor package of claim 13, wherein the semiconductor package comprises a chip-on-film (COF) package.
